(19) United States
(12) Patent Application Publication
(10) Pub. No.: US 2026/0169199 A1
(43) Pub. Date: Jun. 18, 2026

(54) LIFETIME STABILIZATION OF COATED OPTICAL SYSTEMS THROUGH ELECTRON BEAM HEATING

(71) Applicant: Carl Zeiss SMT GmbH, Oberkochen (DE)

(72) Inventors: Matthias KAES, Aalen (DE); Stefan LINK, Ettenstatt (DE); Pavel ALEXEEV, Neresheim (RU)

(21) Appl. No.: 19/421,412

(22) Filed: Dec. 16, 2025

Related U.S. Application Data
(63) Continuation of application No. PCT/EP2024/066443, filed on Jun. 13, 2024.

(30) Foreign Application Priority Data
Jun. 16, 2023 (DE) 10 2023 205 640.2

(51) Int. Cl. G02B 1/12; H01J 37/06; H01J 37/317

(52) U.S. Cl. CPC G02B 1/12; H01J 37/317; H01J 37/06; H01J 2237/0473

(57) ABSTRACT

A method for stabilizing an optical element includes providing an optical element having a substrate and a coating, and subjecting the optical element to heat treatment. The heat treatment of the optical element includes irradiating the coating of the optical element with electrons. Also disclosed are an associated optical element, a microlithographic projection lens having such an optical element, and a microlithographic projection exposure apparatus including such a projection lens, as well as an associated device for electron irradiation.

### CROSS-REFERENCE TO RELATED APPLICATION

This is a Continuation of International Application PCT/EP2024/066443, which has an international filing date of Jun. 13, 2024, and the disclosure of which is incorporated in its entirety into the present Continuation by reference. This Continuation also claims foreign priority under 35 U.S.C. § 119(a)-(d) to and also incorporates by reference, in its entirety, German Patent Application DE 10 2023 205 640.2 filed Jun. 16, 2023.

### FIELD

The invention relates to a method for stabilizing an optical element, the method comprising: providing an optical element with a substrate and a coating, and tempering the optical element. Moreover, the invention relates to an optical element for a projection exposure apparatus, to a microlithographic projection lens having such an optical element and to a microlithographic projection exposure apparatus having such a projection lens, and also to a device for electron irradiation.

### BACKGROUND

Microlithographic projection exposure apparatuses rely on the optical elements used for imaging a mask into an image plane having a high accuracy. Equally high demands are placed on the surface shape of the masks themselves. However, the optical elements are exposed to high temperature loads during the operation of the apparatuses, and this may cause unwanted changes, which might lead to unwanted imaging properties, in the substrate and the coating of the optical elements.

In order to prevent unwanted changes in the optical elements on account of temperature loads during the operation, attempts have been made to stabilize the optical elements by tempering prior to first use. However, owing to the limitations of the permissible temperature, the optical elements cannot be brought to a temperature necessary for the complete stabilization of lifetime effects in a conventional tempering oven. Instead, there is a need for e.g. complex tempering processes that allow cooling of the attachments.

### SUMMARY

One object of the present invention is to provide a method and an optical element that address and/or solve the above-described disadvantages of the prior art. A further object of the present invention is to specify a projection lens and a projection exposure apparatus that have an improved optical element, and an advantageous device for electron irradiation.

According to a first aspect, for a method for stabilizing an optical element, the method comprising: providing an optical element with a substrate and a coating, and tempering the optical element, the problem is solved by virtue of tempering of the optical element comprising irradiating the coating of the optical element with electrons.

The method comprises providing an optical element. The optical element might be a reflective optical element, for example a mirror or a mask. It is also feasible that the optical element is a lens element, a prism, a hologram and/or a diffusing plate. The optical element comprises a substrate and a coating. For example, the substrate might comprise SiSiC, Zerodur® by Schott AG or ULE® by Corning Inc., quartz glass and/or any other type of glass. The coating may comprise one or more layers. The coating is preferably electrically conductive. In particular, this is a metallic coating. The coating may be a coating suitable for the extreme ultraviolet (EUV) wavelength range. For example, this may be a MoSi coating.

The coating may comprise at least one layer subsystem. The layer subsystem may comprise at least one layer, which is formed or synthesized as a compound from at least one material from the group: nickel, carbon, boron carbide, cobalt, beryllium, silicon, silicon oxides. These materials firstly have a sufficiently high absorption coefficient for EUV radiation and secondly at least do not change substantially under EUV radiation. The layer arrangement of the at least one layer subsystem may for example comprise a periodic sequence of at least two periods of individual layers. The periods may comprise individual layers of different materials. The materials of the individual layers forming the periods may for example be nickel and silicon or cobalt and beryllium.

Preferably, the coating may comprise a reflection layer. The reflection layer may comprise at least one layer subsystem that is optimized for the reflection of EUV radiation, in particular radiation at a wavelength of 13 nm or 7 nm. The reflection layer may comprise a periodic sequence of at least one period of individual layers. The period may comprise individual layers with different refractive indices, e.g. in the EUV wavelength range. However, aperiodic layers or a reflection layer that merely comprises one layer are also possible.

Optionally, a protective layer may be applied between the substrate and the reflection layer. The protective layer is intended to prevent the substrate from compacting, e.g. due to EUV used radiation, i.e. the radiation used in an EUV projection exposure apparatus. Here, the layer arrangement of the protective layer may at least comprise a thickness of greater than 20 nm, in particular greater than 50 nm, such that the transmission of EUV radiation through the layer arrangement is less than 10%, in particular less than 2%.

The method comprises tempering the optical element. Tempering may be understood to mean a heat treatment during which the coating of the optical element is heated. In particular, the method comprises tempering the coating of the optical element. For example, the coating of the optical element may be heated at least partially uniformly. The coating of the optical element may be stabilized vis-à-vis lifetime effects as a result of tempering this coating of the optical element. In particular, this allows the coating to be stabilized vis-à-vis a heat input for the later application. For example, tempering may be performed in advance during the production process for the optical element. Unwanted changes in the coating, for example in the layer stress, may thus be advantageously avoided. Moreover, the substrate may be tempered at least in part. In particular, at least regions of the substrate that are close to the surface are tempered. For example, this may refer to regions that are below the surface of the optical element at a depth of up to 5500 nm, preferably up to 3400 nm and particularly preferably up to 1700 nm.

Tempering of the optical element comprises irradiating the coating of the optical element with electrons. In this case, the electron energy is introduced locally in the coating, in particular in at least one layer. It has been recognized that the optical element, in particular the coating of the optical element, can advantageously be heated by electron irradiation. Tempering is implemented in particular by virtue of the irradiation leading to the electron energy being deposited in the coating of the optical element. When irradiating the coating with electrons, the electron energy may be converted into heat through a collision chain. Hence, the coating may be heated in a targeted manner and thus pre-aged as a result of the irradiation with electrons. The heat input in turn may lead to relaxation processes that stabilize the coating of the optical element vis-à-vis heat input for later applications of the optical element. In particular, the coating of the optical element is irradiated such that at least the coating is stabilized. Process parameters can be assigned to a desired stabilizing effect in accordance with a suitable calibration.

Electron irradiation is implemented in vacuo, in particular in a high vacuum. To this end, the optical element may be introduced into a vacuum chamber of a vacuum apparatus. The vacuum apparatus may contain an electron beam source—in particular an electron gun—that generates an electron beam. An electron gun may refer to an electrical arrangement for generating electron beams. The electron gun provides a focused and directed electron beam. For example, the electron beam may have a diameter of 0.1 mm to 20 mm.

It is possible to raster-scan over the surface of the coating of the optical element using the electron beam. Raster-scanning is preferably implemented multiple times, for example two to 10,000 times. Repeated thermal loading on account of multiple raster-scanning processes leads to a stabilization of lifetime effects. For example, raster-scanning may be implemented point by point. The field to be irradiated may be divided into discrete points. The electron beam may be directed at at least one discrete point on the surface and may dwell at this point for a specific time. For example, the dwell time Δt of the electron beam is 10 ns to 10 ms. During this time interval, an isolated local temperature peak may arise at the discrete point. The temperature may suddenly rise rapidly as a result of the heat input. The temperature drops again as soon as the beam is at the next point. Electron irradiation allows the optical element, in particular the coating, to be heated locally to much higher temperatures than would be possible using a tempering oven, for example. Owing to the strong temperature dependence of the relaxations, the temperature peaks can be used for stabilization. In addition to the temperature peaks, there may also be a net increase in the temperature ΔT of the coating of the optical element over time.

Moreover, further parts of the optical element, especially of the substrate of the optical element, may be influenced, in particular stabilized, as a result of irradiating the coating of the optical element with electrons. For example, the substrate of the optical element may also be at least partially heated by the heat generated in the coating. Especially parts of the substrate close to the surface may also be heated as a result of irradiating the coating with electrons. The heat may transfer to further parts of the optical element. These parts of the optical element may likewise be stabilized as a result. By irradiating the coating of the optical element with electrons, it is thus also possible to advantageously stabilize parts of the optical element beyond the coating vis-à-vis lifetime effects.

In particular, compactions introduced into the substrate may be at least partially stabilized. For example, tempering may lead to a partial reduction in compaction previously introduced into the substrate, i.e. lead to a decompaction. Decompaction is an effect that occurs over time when the substrate is used in a projection exposure apparatus, for example in an EUV projection exposure apparatus, and that may therefore lead to a non-negligible change in the surface of the optical element. Tempering accelerates the decompaction process, as a result of which the remaining change by decompaction over the lifetime of the substrate may be advantageously reduced to a negligible value.

Hence, the method allows optical elements to be optimized in a targeted manner, for example during production or else subsequently. It was found that optical elements can be advantageously stabilized, especially vis-à-vis lifetime effects, through the present method. The method allows targeted heat input, which entails local relaxation processes. By virtue of the coating of the optical element being irradiated with electrons, the coating of the optical element and optionally regions of the substrate close to the surface can be tempered in a targeted manner. In particular, unwanted heating of temperature-sensitive attachments, for example adhesively bonded attachments, is avoided in this context. Thermally induced compaction phenomena of the substrate material of an optical element during use may be avoided by the stabilization according to the present method.

In comparison with tempering based on alternative energy sources, for example laser radiation, tempering through electron irradiation inter alia additionally offers the advantage that the electron absorption is largely independent of the optical properties of the optical element. The method may thus be used for different metallic coatings in particular without increased adaptation outlay.

Moreover, the backscattered electrons are largely undirected. In particular, the coating of the optical element may backscatter the electrons incident thereon. The backscattered electrons being largely undirected is advantageous in that there are no reflection zones requiring cooling within the vacuum chamber. In contrast thereto, laser radiation in particular is directed and may require a cooled absorber.

According to a first advantageous configuration of the method, the electron energy E_{Temp} for tempering is chosen depending on the thickness of the coating of the optical element. For example, the thickness of the coating is up to 500 nm, preferably up to 450 nm and particularly preferably up to 400 nm. In particular, the electron energy E_{Temp} for tempering is chosen depending on the thickness of at least one layer of the coating of the optical element. Hence, the coating may advantageously be heated locally. It has been recognized that the penetration depth of the electrons is influenced by the electron energy. The greater the electron energy, the deeper the penetration depth of the electrons. To a first approximation, the stopping power in this case decreases inversely proportional to the electron energy. Most of the energy is deposited at the end of the trajectory where the electrons have been decelerated to zero. A targeted local introduction of heat can be ensured in this way. The heating depth may be set with the electron energy. For example, the electron energy E_{Temp} may be chosen such that the energy is introduced locally in the coating, especially in at least one layer. The electron energy E_{Temp} may be adapted to different coatings. Preferably, the electron energy E_{Temp} is chosen such that the electron energy E_{Temp} is at least substantially completely absorbed in the coating of the optical element. For example, the electron energy E_{Temp} is chosen such that the energy is absorbed exclusively in the coating, especially in at least one layer. Penetration of electrons into underlying layers or into the substrate of the optical element should preferably be avoided in order to avoid unwanted effects such as unwanted compaction, for example. Therefore, a low electron energy E_{Temp} is preferably chosen for the tempering.

In particular, the acceleration voltage U_{Temp} for tempering is chosen depending on the thickness of the coating of the optical element, especially of at least one layer. In particular, the electron energy E_{Temp} depends on the voltage for accelerating the electrons, the acceleration voltage U_{Temp}. The electron energy E_{Temp} and hence the penetration depth of the electrons in particular may be influenced with the aid of the acceleration voltage U_{Temp}.

According to a further advantageous configuration of the method, the acceleration voltage U_{Temp} for tempering is 1 to 30 keV, preferably 1 to 10 keV, further preferably 11 to 15 keV, further preferably 16 to 20 keV and further preferably 21 to 30 keV. Preferably, the acceleration voltage U_{Temp} is less than 30 keV. Energy may be deposited in the coating of the optical element in a targeted manner with correspondingly low acceleration voltages. In particular, the energy may be introduced locally into at least one capping layer of the optical element. For example, an acceleration voltage U_{Temp} in the range of 1 to 30 keV may be chosen depending on the thickness of the at least one layer that should be stabilized. For example, the acceleration voltage U_{Temp} may be 5 keV. The acceleration voltage U_{Temp} may be calculated depending on the layer system.

According to a further advantageous configuration of the method, the current intensity I_{Temp} for tempering is 0.1 to 5 mA. Powers ranging from 0.1 to 100 W may be generated using an acceleration voltage U_{Temp} in the range from 1 to 20 keV and a current intensity I_{Temp} in the range from 0.1 to 5 mA. Preferably, the current intensity I_{Temp} for tempering is 0.5 to 5 mA, particularly preferably more than 0.5 mA. While the penetration depth of the electrons is set with the acceleration voltage U_{Temp} in particular, the power may be additionally adjusted with the current intensity I_{Temp}. As a result, it is possible to influence the temperature in turn. For example, a higher current intensity I_{Temp} may be chosen in order to obtain a higher power and hence higher temperatures. For example, the duration of the irradiation may be shortened hereby.

According to a further advantageous configuration of the method, the temperature during tempering is ≥60°C. A temperature of ≥60°C. may be achieved locally in the coating and optionally in regions of the substrate close to the surface as a result of irradiating the coating with electrons. For example, the temperature is 60° C. However, significantly higher temperatures are also feasible. The temperature is thus disproportionately high in comparison with e.g. storage over a relatively long time at room temperature, as a result of which stabilization can be ensured. During tempering, temperature gradients may arise at interfaces, whereby the coating may be heated disproportionately and lifetime effects of the coating and regions close to the surface may be stabilized at least virtually completely.

According to a further advantageous configuration of the method, the method further comprises: at least partially compacting the substrate of the optical element, wherein the compacting comprises irradiating the optical element with electrons. Hence, the method may comprise compacting a substrate of an optical element through electron irradiation and tempering the optical element through electron irradiation. The flexibility of the processing can be increased by the independent electron irradiation processes. The substrate may be compacted locally by irradiation with electrons. In this case, the substrate material may be compacted locally in the long term by the irradiation. This may lead to a change, in particular a correction, of the surface shape of the optical element in the vicinity of the irradiated regions. This may compensate for surface defects left behind by preliminary processes, in particular coating processes. The compaction, especially compaction in regions of the substrate close to the surface, can preferably be stabilized with the aid of the irradiation of the coating of the optical element.

Preferably, the electron energy E_{Komp} used for compacting is greater than the electron energy E_{Temp} used for tempering. A deeper penetration depth may be obtained thereby. In particular, this allows the electron energy E_{Komp} to be deposited into the substrate below the coating of the optical element in order to achieve local compaction. The effective zones for correction and tempering are thus different.

The acceleration voltage U_{Komp} for compacting is preferably more than 30 keV, particularly preferably 31 to 40 keV, further particularly preferably 41 to 50 keV, further particularly preferably 51 to 60 keV, further particularly preferably 61 to 70 keV, further particularly preferably 71 to 80 keV, further particularly preferably 81 to 90 keV and further particularly preferably 91 to 100 keV. Compacting is preferably implemented in a range between 1 μm and 100 μm, particularly preferably between 1 μm and 10 μm, further particularly preferably between 11 μm and 20 μm, further particularly preferably between 21 μm and 30 μm, further particularly preferably between 31 μm and 40 μm, further particularly preferably between 41 μm and 50 μm, further particularly preferably between 51 μm and 60 μm, further particularly preferably between 61 μm and 70 μm, further particularly preferably between 71 μm and 80 μm, further particularly preferably between 81 μm and 90 μm and further particularly preferably between 91 μm and 100 μm below the coating of the optical element.

The substrate of the optical element is preferably compacted before the optical element is tempered or substantially simultaneously therewith. In particular, the substrate of the optical element is irradiated before the coating of the optical element is irradiated or substantially simultaneously therewith. Both the coating and the introduced compaction may advantageously be stabilized hereby. Moreover, tempering may be performed in situ. Compacting and tempering may be performed in situ and in parallel or in succession. In this case, the acceleration voltages U_{Komp} and U_{Temp} of the respective processes may be matched to one another. While the tempering takes place at the surface in the coating of the optical element, the compaction is generated in an underlying layer in the substrate. The two processes are matched to one another such that the heating is efficient, and the compacting is not negatively influenced by the tempering. To this end, the acceleration voltage U_{Komp} for compacting is preferably chosen to be slightly greater than the acceleration voltage U_{Temp} for tempering. The introduced compaction is heated hereby as efficiently as possible. The exact value of the acceleration voltages may be chosen on the basis of the thickness of the coating.

If the substrate is compacted before the optical element is tempered, compaction and stabilization of the optical element may advantageously be performed using the same electron gun. For example, the electron gun may initially be operated at an acceleration voltage U_{Komp} for compacting and subsequently at an acceleration voltage U_{Temp} for tempering.

Compacting the substrate and tempering the optical element may also be implemented substantially simultaneously. Substantially simultaneously means that, in particular, compacting the substrate and tempering the optical element are performed at least substantially at the same time. Substantially simultaneously compacting the substrate and tempering the optical element is understood to mean that, in particular, compacting the substrate and tempering the optical element may be implemented in parallel. For example, different electron guns may be used to this end. The electron guns may be operated at different acceleration voltages U_{Komp} for compacting and U_{Temp} for tempering. The electron guns may be provided in an electron beam apparatus. Hence it is possible to dispense with an additional machine for a downstream tempering process, for example a tempering oven. The method thus allows significant savings in production time and area. Moreover, the layers may be heated in a targeted manner to much higher temperatures by the electron beam than with an oven. Temperatures of ≥60°C., in particular more than 60° C., may be obtained.

It is also feasible that an opposing field, in particular a dynamic opposing field, is applied to the optical element, in particular to the coating of the optical element. Hence the optical element may be irradiated with the same, higher electron energy E_{Komp} both for compacting and for tempering, wherein the electrons can be decelerated in a targeted manner by the opposing field for the purpose of irradiating the coating. This also allows tempering of the coating to be achieved without any change in the voltage source of the electron radiation being required.

According to a second teaching, the aforementioned problem is solved for an optical element, in particular a reflective optical element, by virtue of the optical element having been stabilized by a method according to the first aspect. Lifetime effects of the optical element, in particular of the coating of the optical element, have been stabilized by tempering. The optical element is suitable for use in a projection exposure apparatus in particular. For example, the optical element is a coated mirror. The coating of the substrate of the mirror may comprise at least one layer subsystem that is optimized for the reflection of EUV radiation, i.e. radiation at a wavelength of 13 nm or 7 nm. This reflection layer may comprise a periodic sequence of at least one period of individual layers, wherein the period may comprise two individual layers with different refractive indices in the EUV wavelength range. However, aperiodic layers or coatings that merely comprise one layer are also possible.

According to a third teaching, the aforementioned problem is solved for a microlithographic projection lens by virtue of the projection lens comprising an optical element according to the second aspect. Microlithographic projection lenses are exposed to high loads by the used radiation, the wavelength of which is preferably 13.5 nm, and radiation at other wavelengths, whereby these microlithographic projection lenses are heated during operation. By using an optical element according to the second aspect, which has thus been stabilized by a method according to the first aspect, it is advantageously possible to minimize a change in the surface over time, for example by decompaction of the material.

According to a fourth teaching, the aforementioned problem is solved for a microlithographic projection exposure apparatus by virtue of the projection exposure apparatus comprising a projection lens according to the third aspect. A projection exposure apparatus may be provided to generate, in an image plane, an image of an object arranged in an object plane using a light source that emits projection light. The projection exposure apparatus according to the fourth aspect is a microlithographic projection exposure apparatus. Microlithographic projection exposure apparatuses serve to produce microstructured or nanostructured components for microelectronics or microsystems technology. Projection exposure apparatuses are used to image structures formed on a photomask onto a wafer or the like in reduced fashion in order to generate the corresponding structures on the wafer through microlithographic processes. In particular, a projection exposure apparatus can be an EUV projection exposure apparatus or a deep ultraviolet (DUV) projection exposure apparatus. On account of the increasing miniaturization and reduction of the structure widths, projection exposure apparatuses are operated with operating light with ever shorter wavelengths, for example with wavelengths in the range of extreme ultraviolet light (EUV light).

Projection exposure apparatuses are operated round-the-clock, and every fault has an effect on the performance of the projection exposure apparatus. Servicing times of the projection exposure apparatus can advantageously be reduced by the use of projection optical units with long-term stability.

According to a fifth teaching, the aforementioned problem is solved for a device for electron irradiation comprising a vacuum apparatus with a vacuum chamber, wherein the vacuum apparatus contains an electron beam source, in particular an electron gun, for generating an electron beam, by virtue of the device being configured to generate an opposing field—in particular a dynamic opposing field—that is applied to the optical element, in particular to the coating of the optical element. As a result, the optical element in particular may be irradiated with the same electron energy both for compacting and for tempering, wherein the electrons are decelerated in a targeted manner by the opposing field for the purpose of irradiating the coating.

The present disclosure also comprises the subject matter of the following clauses:

1. A method for stabilizing an optical element, the method comprising:
providing an optical element with a substrate and a coating, and
tempering the optical element,

characterized in that

tempering of the optical element comprises irradiating the coating of the optical element with electrons.

2. The method according to clause 1,

characterized in that

the electron energy E_{Temp}, in particular the acceleration voltage U_{Temp}, for tempering is chosen depending on the thickness of the coating, in particular of at least one layer of the coating, of the optical element.

3. The method according to clause 1 or 2,

characterized in that

the acceleration voltage U_{Temp} for tempering is 1 to 30 keV, preferably 1 to 10 keV, further preferably 11 to 15 keV, further preferably 16 to 20 keV and further preferably 21 to 30 keV.

4. The method according to any of clauses 1 to 3,

characterized in that

the current intensity I_{Temp} for tempering is 0.1 to 25 mA, in particular 0.1 to 5 mA, further particularly 5.1 to 10 mA, further particularly 10.1 to 15 mA, further particularly 15.1 to 20 mA and further particularly 20.1 to 25 mA.

5. The method according to any of clauses 1 to 4,

characterized in that

the temperature during tempering is >60°C.

6. The method according to any of clauses 1 to 5,

characterized in that

the method further comprises:
at least partially compacting the substrate of the optical element, wherein compacting comprises irradiating the optical element with electrons.

7. The method according to clause 6,

characterized in that

the electron energy E_{Komp} used for compacting is greater than the electron energy E_{Temp} used for tempering.

8. The method according to clause 6 or 7,

characterized in that

the acceleration voltage U_{Komp} for compacting is more than 30 keV, particularly preferably 31 to 40 keV, further particularly preferably 41 to 50 keV, further particularly preferably 51 to 60 keV, further particularly preferably 61 to 70 keV, further particularly preferably 71 to 80 keV, further particularly preferably 81 to 90 keV and further particularly preferably 91 to 100 keV.

9. The method according to any of clauses 6 to 8,

characterized in that

the substrate of the optical element is compacted before the coating of the optical element is tempered or substantially simultaneously therewith.

10. An optical element, in particular a reflective optical element, stabilized by a method according to any of clauses 1 to 9.

11. A microlithographic projection lens, comprising an optical element according to clause 10.

12. A microlithographic projection exposure apparatus, comprising a projection lens according to clause 11.

Further configurations and advantages of the invention will be explained in conjunction with the drawing in the detailed description below of a few exemplary embodiments.

### BRIEF DESCRIPTION OF THE DRAWING

Exemplary embodiments, including variants, of the invention will be explained in detail below on the basis of the drawing. The aspects of the disclosure can be understood best from the detailed description below in conjunction with the appended figures. The figures are schematic and simplified; they only show details to improve the understanding of the claims, while other details are omitted. The same reference numerals are used throughout for identical or corresponding parts. The individual features of each aspect may in each case be combined with any desired or all features of the other aspects. These and other aspects, features and/or technical effects are evident from the figures described below and are clarified by said figures:

FIG. 1 shows a schematic illustration of an embodiment of a projection exposure apparatus according to the fourth aspect,

FIG. 2 shows a diagram showing the variation in the maximum penetration depth of electrons into a MoSi coating of an optical element as a function of the electron energy,

FIGS. 3A-3C show simulations of the trajectories of electrons that were introduced into an optical element at 5 keV (FIGS. 3A), 15 keV (FIGS. 3B) and 55 keV (FIG. 3C) by an embodiment of a method according to the first aspect,

FIGS. 4A-4B show schematic illustrations of embodiments of a method involving compacting (FIG. 4A) and tempering (FIG. 4B) according to the first aspect for stabilizing an optical element,

FIGS. 5A-5B show, respectively, an irradiation field for performing an embodiment of a method according to the first aspect for stabilizing an optical element (FIG. 5A) and a development of the temperature for discrete points in the irradiation field (FIG. 5B), and

FIG. 6 shows a schematic illustration of an apparatus for electron irradiation for performing an embodiment of a method according to the first aspect for stabilizing an optical element.

### DETAILED DESCRIPTION

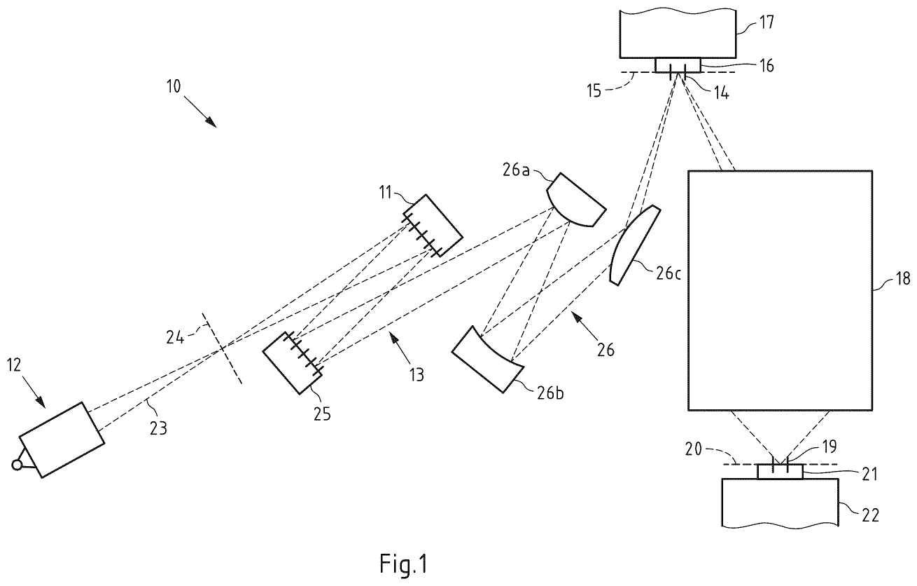

FIG. 1 shows by way of example a basic construction of a microlithographic projection exposure apparatus 10 in which the invention can find application. An illumination system of the projection exposure apparatus 10 has, in addition to a light source 12, an illumination optics unit 13 for the illumination of an object field 14 in an object plane 15. Extreme ultraviolet (EUV) radiation 23 in the form of optical used radiation generated by the light source 12 is aligned with a collector, which is integrated in the light source 12, so that it passes through an intermediate focus in the region of an intermediate focal plane 24 before it is incident on a field facet mirror 11. Downstream of the field facet mirror 11, the EUV radiation 23 is reflected off a pupil facet mirror 25. With the aid of the pupil facet mirror 25 and an optical assembly 26 with mirrors 26a, 26b and 26c, field facets of the field facet mirror 11 are imaged into the object field 14.

A reticle 16 arranged in the object field 14 and held by a schematically depicted reticle holder 17 is illuminated. A merely schematically depicted projection optics unit 18 serves for imaging the object field 14 into an image field 19 in an image plane 20. A structure on the reticle 16 is imaged onto a light-sensitive layer of a wafer 21, which is arranged in the region of the image field 19 in the image plane 20 and is held by a wafer holder 22, which is likewise depicted in sections. The light source 12 may emit used radiation, in particular in a wavelength range between 5 nm and 30 nm.

Embodiments of the invention may likewise be used in a DUV projection apparatus, which is not illustrated. A DUV apparatus is set up in principle like the above-described EUV projection apparatus 10, wherein mirrors and lens elements can be used as optical elements in a DUV apparatus and the light source of a DUV apparatus emits used radiation in a wavelength range from 100 nm to 300 nm.

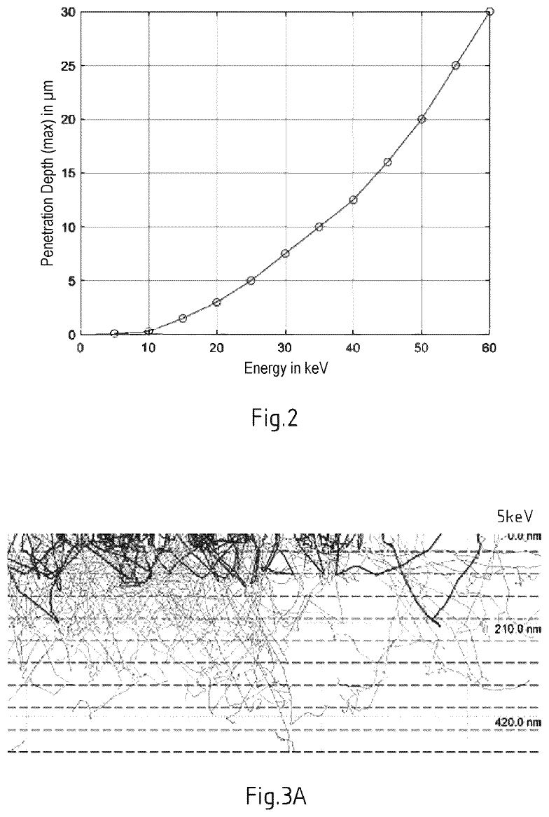

FIG. 2 shows the variation of the maximum penetration depth of electrons into a layer system of a MoSi coating of an optical element for different amounts of electron energy. It has been recognized that when an optical element is irradiated by electrons, the penetration depth of the electrons is influenced by the electron energy. For example, the heating depth may thus be set through the electron energy. The greater the electron energy, the deeper the penetration depth of the electrons. As a result, the coating of the optical element may be irradiated in a targeted manner by virtue of the electron energy being adapted to e.g. the thickness of the coating. This makes it possible to ensure that the electron energy E_{Temp} for tempering is deposited at least substantially completely in the coating of the optical element, and the coating is thus locally tempered. By contrast, a higher electron energy E_{Komp} may be chosen for compacting the substrate of the optical element, in order to locally compact the substrate in a targeted manner.

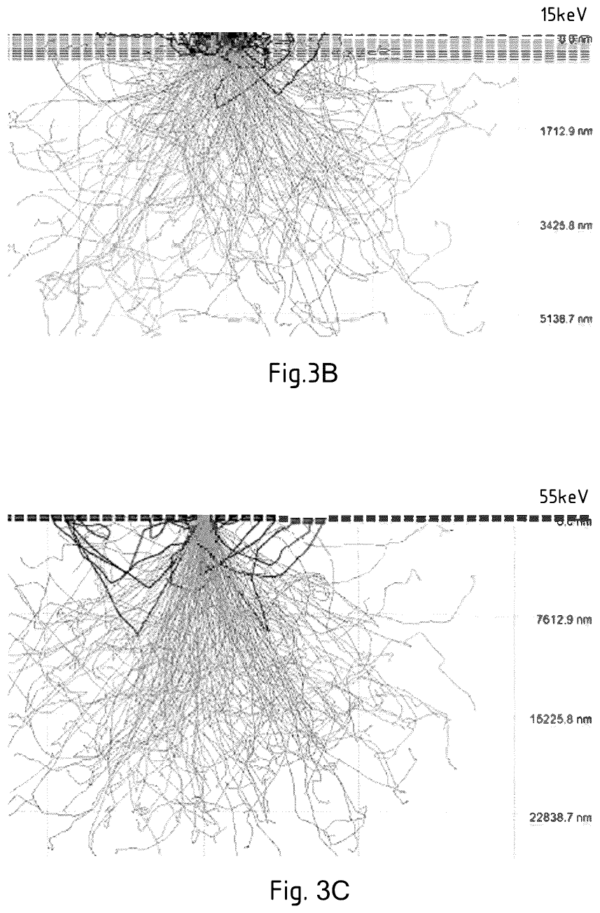

FIGS. 3A to 3C show trajectories of simulated electron beams. Here, the bright lines represent the simulated trajectories of the penetrating electrons. The trajectories illustrated by dark lines represent electrons that leave the material again in the scattering process. The respective material depths are specified on the right-hand side of the figures. FIG. 3A shows a simulation of the trajectories at an electron energy of 5 keV. At an electron energy of 5 keV, the electrons do not pass into the substrate of the optical element, which begins below the lowermost dashed line. FIGS. 3B and 3C analogously show the trajectories for electron energies of 15 keV and 55 keV, respectively. In FIG. 3B, the electrons also penetrate into surface-near regions of the substrate of the optical element that is arranged below the coating. In this case, the electrons reach penetration depths of up to approximately 5500 nm below the surface of the optical element. At an electron energy of 55 keV, the electrons penetrate significantly deeper into the substrate, as shown in FIG. 3C.

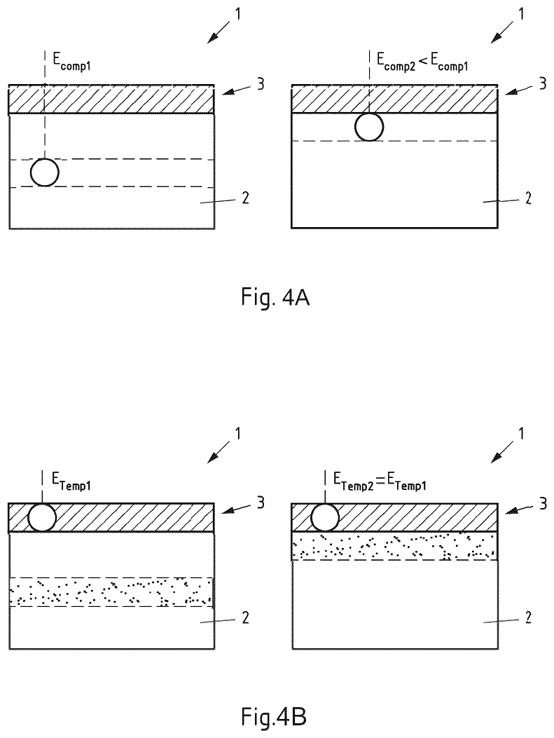

FIGS. 4A and 4B show compacting a substrate of an optical element through electron irradiation and subsequent tempering the optical element through electron irradiation. FIG. 4A illustrates an irradiation of an optical element 1 with an electron energy E_{Komp1} (left) for compacting the substrate 2 of the optical element 1. Following the compacting, the coating 3 of the optical element 1 is irradiated in order to temper it, as shown in FIG. 4B (left). Both the coating 3 and the introduced compaction can be stabilized by tempering.

Should the heat introduced at depth by tempering be insufficient, adapting the processing parameters during compaction, in particular the electron energy E_{Komp2} and hence the depth of the compaction zone, makes it possible to enable effective tempering of the coating 3 and compaction of the optical element 1. The penetration depth of the electrons depends on the electron energy. The electron energy E_{Komp2} may be chosen to be lower than the electron energy E_{Komp}, whereby the electrons penetrate into the substrate 2 to a lower depth in order to compact the substrate material there, as shown in FIG. 4A (right). The electron energy E_{Temp1} during tempering in FIG. 4B (right) is not modified as it is adapted to the layer system 3 of the optical element 1.

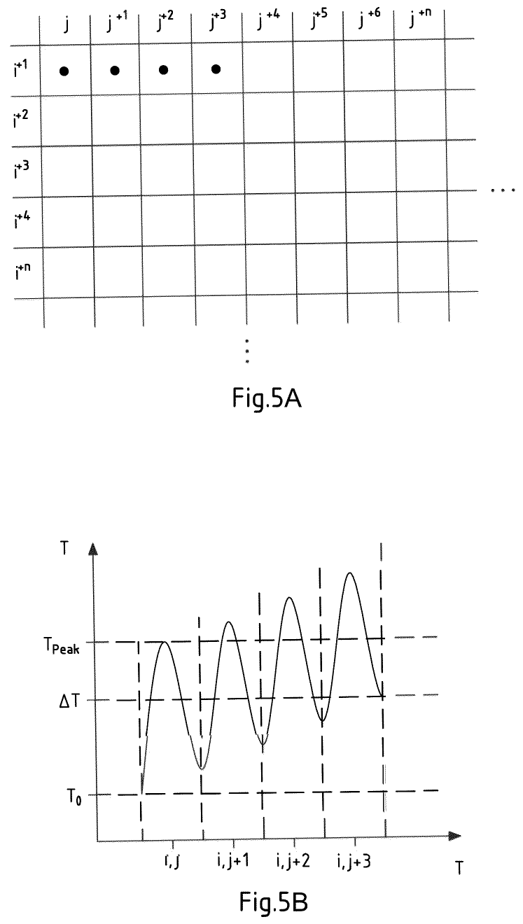

FIG. 5A shows the division of an irradiation field for irradiating the coating of an optical element into discrete points i,j. It is possible to raster-scan over the surface of the coating of the optical element using an electron beam. Raster-scanning is preferably implemented multiple times, for example two to 10,000 times. The electron beam may be directed at at least one discrete point i,j on the surface and may dwell at this point for a specific time. For example, the dwell time Δt of the electron beam is 10 ns to 10 ms. During this time interval, an isolated local temperature peak may arise at the discrete point, as evident from FIG. 5B. The temperature may suddenly rise rapidly as a result of the heat input. FIG. 5B outlines the temperature development at each point i,j; i,j+1; etc. Should the electron beam dwell at one point, the temperature T suddenly rises on account of the heat input but drops off again as soon as the beam is at the next point. In addition to the temperature peaks, there is also a net increase in the temperature ΔT of the overall mirror over time. Owing to the strong temperature dependence of the relaxations, the temperature peaks can be used for stabilization.

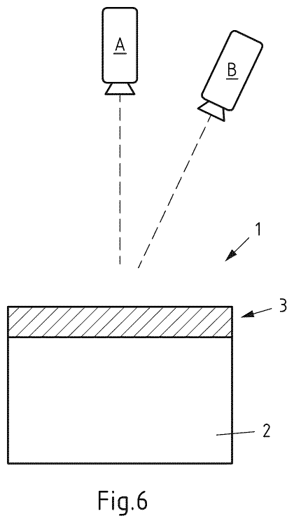

FIG. 6 shows an apparatus for electron irradiation having two electron guns A, B. Electron gun A serves for compacting the substrate 2, while the coating 3 of the optical element 1 is irradiated with the aid of electron gun B. Compacting the substrate 2 and tempering the optical element 1 are implemented substantially simultaneously. To this end, the electron guns A, B are operated at different acceleration voltages U_{Komp} for compacting the substrate 2 and U_{Temp} for tempering the optical element 1. Electron gun A is operated at an acceleration voltage U_{Komp} of 60 keV, while electron gun B is operated at an acceleration voltage U_{Temp} of 10 keV. The current intensity I_{Komp} for compacting is 0.1 mA, whereby a power P_{Komp} of 6 W is attained. The current intensity I_{Temp} for tempering is 2 mA, whereby a power P_{Komp} of 20 W is attained. It is possible herewith to achieve temperatures of ≥60°C. in the coating 3 of the optical element 1 and hence a stabilization of the coating 3 and regions of the substrate 2 close to the surface.

What is claimed is:

1. A method for stabilizing an optical element, comprising:
providing the optical element with a substrate and a coating;
tempering the optical element,
wherein said tempering of the optical element comprises irradiating the coating of the optical element with electrons; and
at least partially compacting the substrate of the optical element, wherein said compacting of the substrate comprises irradiating the optical element with electrons,
wherein said compacting of the substrate of the optical element is performed either before or substantially simultaneously with said irradiating of the coating of the optical element.

2. The method as claimed in claim 1, further comprising:
selecting an electron energy for said tempering according to a thickness of the coating of the optical element.

3. The method as claimed in claim 1, further comprising:
selecting an acceleration voltage for said tempering according to a thickness of at least one layer of the coating of the optical element.

4. The method as claimed in claim 2, wherein
the electron energy is selected according to a thickness of at least one layer of the coating of the optical element.

5. The method as claimed in claim 3, wherein
the acceleration voltage for said tempering is between 1 keV and 30 keV.

6. The method as claimed in claim 5, wherein
the acceleration voltage for said tempering is between 21 keV and 30 keV.

7. The method as claimed in claim 1, wherein
a current intensity for said tempering is between 0.1 mA and 25 mA.

8. The method as claimed in claim 7, wherein
the current intensity for said tempering is between 20.1 mA and 25 mA.

9. The method as claimed in claim 1, wherein
a temperature for said tempering is >60°C.

10. The method as claimed in claim 1, further comprising:
selecting an electron energy for said compacting to be greater than an electron energy for said tempering.

11. The method as claimed in claim 1, further comprising:
selecting an acceleration voltage for said compacting to be more than 30 keV.

12. The method as claimed in claim 11, wherein
the acceleration voltage for said compacting is between 91 keV and 100 keV.

13. The method as claimed in claim 1, further comprising:
applying an opposing field to the optical element.

14. The method as claimed in claim 13, wherein
the opposing field is a dynamic opposing field.

15. The method as claimed in claim 13, wherein
the opposing field is applied to the coating of the optical element.

16. The method as claimed in claim 13, further comprising:
selecting an electron energy; and
irradiating the optical element with the electron energy equally for both said compacting and said tempering,
wherein the electrons are decelerated in a targeted manner by the opposing field.

17. A device for electron irradiation, comprising:
a vacuum apparatus comprising a vacuum chamber and at least one electron beam source for generating an electron beam, and
a field generator configured to generate an opposing field.

18. The device as claimed in claim 17, wherein
the electron beam source is configured as an electron gun, and
the field generator is configured to generate a dynamic opposing field.
